(19) United States
(12) Patent Application Publication
(10) Pub. No.: US 2022/0021178 A1
(43) Pub. Date: Jan. 20, 2022

(54) ELECTRONIC DEVICE AND METHOD FOR CONTROLLING OUTPUT OF LIGHT SOURCES OF ELECTRONIC DEVICE

(71) Applicant: SAMSUNG ELECTRONICS CO., LTD., Suwon-si (KR)

(72) Inventors: Byeonghoon PARK, Suwon-si (KR); Yongchan KEH, Suwon-si (KR); Woontahk SUNG, Suwon-si (KR)

(21) Appl. No.: 17/449,498

(22) Filed: Sep. 30, 2021

Related U.S. Application Data
(63) Continuation of application No. PCT/KR2020/003670, filed on Mar. 18, 2020.

(30) Foreign Application Priority Data
Apr. 3, 2019 (KR) 10-2019-0038858

(51) Int. Cl. H01S 5/00; G01J 1/44; H01S 5/02257; H01S 5/068

(52) U.S. Cl. CPC H01S 5/0014; G01J 1/44; G01S 7/484; H01S 5/06808; G01J 2001/446; H01S 5/02257

(57) ABSTRACT

An electronic device according to various embodiments may comprise: a circuit board; a plurality of light sources mounted on the circuit board; a first detection circuit arranged adjacent to the plurality of light sources and mounted on the circuit board; and a casing including a body portion mounted on the circuit board and surrounding at least a portion of an area in which the plurality of light sources and the first detection circuit are arranged, and a window mounted on the body portion facing the plurality of light sources, wherein the window may include a diffuser formed on at least one surface of the window and configured to disperse light emitted from the plurality of light sources and a second detection circuit at least partially surrounding the diffuser on the outer surface of the window.

### CROSS-REFERENCE TO RELATED APPLICATIONS

This application is a continuation of International Application No. PCT/KR2020/003670 designating the United States, filed on Mar. 18, 2020, in the Korean Intellectual Property Receiving Office and claiming priority to Korean Patent Application No. 10-2019-0038858, filed on Apr. 3, 2019, in the Korean Intellectual Property Office, the disclosures of which are incorporated by reference herein in their entireties.

### BACKGROUND

### Field

The disclosure relates to an electronic device capable of detecting damage to a light source module in the electronic device, and a method for controlling output of a light source of an electronic device.

### Description of Related Art

A high-output laser diode may be applied to a camera of an electronic device as a depth sensor IR light source using a time-of-flight (ToF) scheme or a structured light scheme.

However, due to the coherent characteristics of laser beams, electronic devices using high-output lasers, in particular, must follow strict international standards regarding eye-safety (IEC-60825), and systems must independently have interlock protection or satisfy class-1 grades.

If an electronic device includes a light source module capable of using a high-output laser, the light source module includes a diffuser area for diffusing light emitted (or output) from the high-output laser. However, if the diffuser area undergoes damage (for example, crack, scratch, dust, partial removal, or the like) due to a drop of the electronic device or accumulated impacts, the user's eye safety may be affected.

### SUMMARY

Embodiments of the disclosure may provide an electronic device and a method for controlling output of a light source of the electronic device, wherein if a diffuser area of a light source module using a high-output laser is damaged, light emission of the high-output laser can be controlled.

Embodiments of the disclosure may provide an electronic device and a method for controlling output of a light source of the electronic device, wherein damage to a diffuser area can be sensed using a light source module having a simple driving circuit.

According to various example embodiments, an electronic device may include: a circuit board, multiple light sources mounted on the circuit board, a first detection circuit arranged adjacent to the multiple light sources and mounted on the circuit board, a casing including a body mounted on the circuit board and configured to surround at least a portion of an area in which the multiple light sources and the first detection circuit are arranged, and a window mounted on the body and facing the multiple light sources, wherein the window includes a diffuser formed on at least one surface thereof configured to diffuse light emitted from the multiple light sources, and a second detection circuit at least partially surrounding the diffuser on the outer surface of the window.

According to various example embodiments, a method for controlling an output of a light source of an electronic device may include: emitting light from multiple light sources; determining whether a diffuser configured to diffuse light emitted from the multiple light sources is damaged using at least one of a first detection circuit or a second detection circuit included the electronic device during emitting light from the multiple light sources; and controlling light emission of the multiple light sources, based on the determination of whether the diffuser is damaged.

According to various example embodiments, upon sensing damage to a diffuser area of a light source due to a drop of an electronic device, accumulated impacts, or the like, output of the light source may be controlled to protect the user's eye safety.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram of illustrating an example electronic device in a network environment according to various embodiments;

FIG. 2 is a block diagram illustrating an example configuration of a camera module according to various embodiments;

FIG. 3 is a block diagram illustrating an example configuration of a light source output control device according to various embodiments;

FIG. 4A is a diagram illustrating a light source module of an electronic device according to various embodiments;

FIG. 4B is a cross-sectional view taken along line A-A′ of FIG. 4A according to various embodiments;

FIG. 5A is a circuit diagram of a circuit for controlling a light source module in an electronic device according to various embodiments;

FIG. 5B is a graph illustrating a change of a voltage value due to damage to a diffuser in an electronic device according to various embodiment;

FIG. 6 is a circuit diagram for controlling a light source module in an electronic device according to various embodiments.

FIG. 7 is a circuit diagram of a circuit for controlling a light source module in an electronic device according to various embodiments; and

FIG. 8 is a flowchart illustrating an example operation of controlling a light source module in an electronic device according to various embodiments.

### DETAILED DESCRIPTION

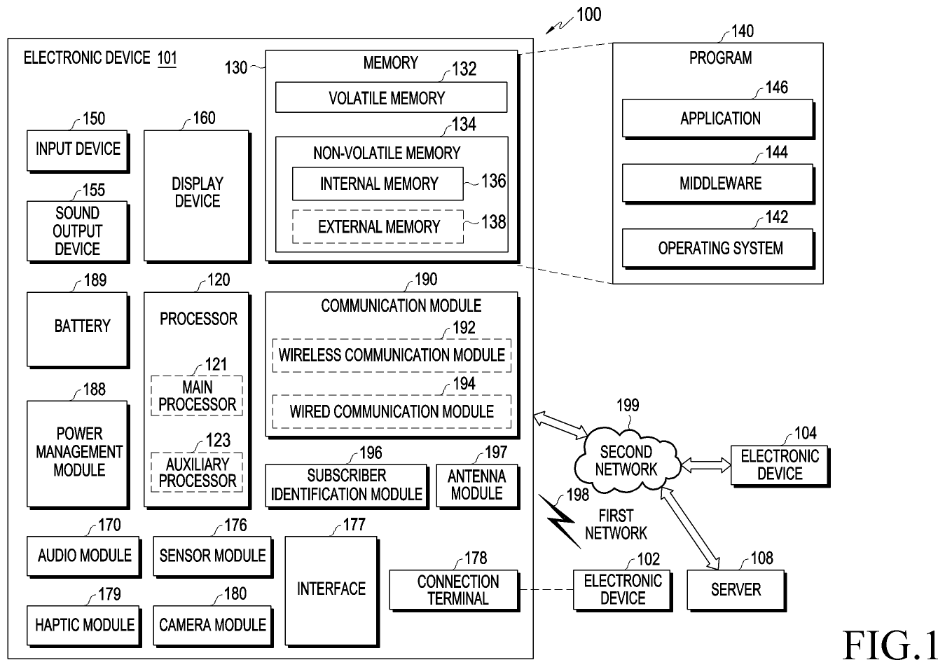

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input device 150, a sound output device 155, a display device 160, an audio module 170, a sensor module 176, an interface 177, a haptic module 179, a camera module 180, a power management module 188, a battery 189, a communication module 190, a subscriber identification module (SIM) 196, or an antenna module 197. In various embodiments, at least one (e.g., the display device 160 or the camera module 180) of the components may be omitted from the electronic device 101, or one or more other components may be added in the electronic device 101. In various embodiments, some of the components may be implemented as single integrated circuitry. For example, the sensor module 176 (e.g., a fingerprint sensor, an iris sensor, or an illuminance sensor) may be implemented as embedded in the display device 160 (e.g., a display).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may load a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), and an auxiliary processor 123 (e.g., a graphics processing unit (GPU), an image signal processor (ISP), a sensor hub processor, or a communication processor (CP)) that is operable independently from, or in conjunction with, the main processor 121. Additionally or alternatively, the auxiliary processor 123 may be adapted to consume less power than the main processor 121, or to be specific to a specified function. The auxiliary processor 123 may be implemented as separate from, or as part of the main processor 121.

The auxiliary processor 123 may control, for example, at least some of functions or states related to at least one component (e.g., the display device 160, the sensor module 176, or the communication module 190) among the components of the electronic device 101, instead of the main processor 121 while the main processor 121 is in an inactive (e.g., sleep) state, or together with the main processor 121 while the main processor 121 is in an active (e.g., executing an application) state. According to an embodiment, the auxiliary processor 123 (e.g., an image signal processor or a communication processor) may be implemented as part of another component (e.g., the camera module 180 or the communication module 190) functionally related to the auxiliary processor 123.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input device 150 may receive a command or data to be used by a component (e.g., the processor 120) of the electronic device 101, from the outside (e.g., a user) of the electronic device 101. The input device 150 may include, for example, a microphone, a mouse, a keyboard, or a digital pen (e.g., a stylus pen).

The sound output device 155 may output sound signals to the outside of the electronic device 101. The sound output device 155 may include, for example, a speaker or a receiver. The speaker may be used for general purposes, such as playing multimedia or playing record, and the receiver may be used for incoming calls. According to an embodiment, the receiver may be implemented as separate from, or as part of the speaker.

The display device 160 may visually provide information to the outside (e.g., a user) of the electronic device 101. The display device 160 may include, for example, a display, a hologram device, or a projector and control circuitry to control a corresponding one of the display, hologram device, and projector. According to an embodiment, the display device 160 may include touch circuitry adapted to detect a touch, or sensor circuitry (e.g., a pressure sensor) adapted to measure the intensity of force incurred by the touch.

The audio module 170 may convert a sound into an electrical signal and vice versa. According to an embodiment, the audio module 170 may obtain the sound via the input device 150, or output the sound via the sound output device 155 or an external electronic device (e.g., an electronic device 102 (e.g., a speaker or a headphone)) directly or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image and moving images. According to an embodiment, the camera module 180 may include one or more lenses, image sensors, image signal processors, or flashes.

The power management module 188 may manage power supplied to the electronic device 101. According to an embodiment, the power management module 388 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and support a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., PCB). According to an embodiment, the antenna module 197 may include a plurality of antennas. In such a case, at least one antenna appropriate for a communication scheme used in the communication network, such as the first network 198 or the second network 199, may be selected, for example, by the communication module 190 from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 and 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, or client-server computing technology may be used, for example.

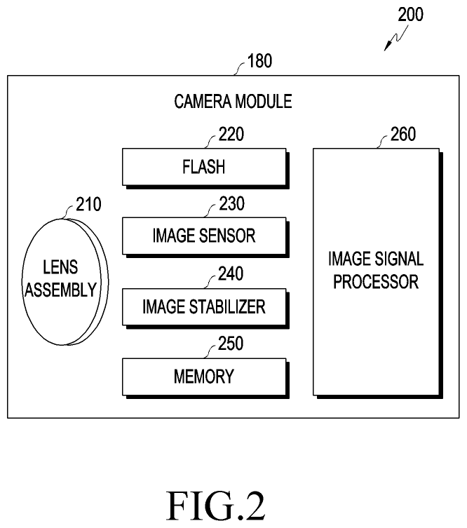

FIG. 2 is a block diagram 200 illustrating an example configuration of the camera module 180 according to various embodiments. Referring to FIG. 2, the camera module 180 may include a lens assembly (e.g., including at least one lens) 210, a flash 220, an image sensor 230, an image stabilizer (e.g., including circuitry) 240, memory 250 (e.g., buffer memory), or an image signal processor (e.g., including processing circuitry) 260. The lens assembly 210 may collect light emitted or reflected from an object whose image is to be taken. The lens assembly 210 may include one or more lenses. According to an embodiment, the camera module 180 may include a plurality of lens assemblies 210. In such a case, the camera module 180 may form, for example, a dual camera, a 360-degree camera, or a spherical camera. Some of the plurality of lens assemblies 210 may have the same lens attribute (e.g., view angle, focal length, auto-focusing, f number, or optical zoom), or at least one lens assembly may have one or more lens attributes different from those of another lens assembly. The lens assembly 210 may include, for example, a wide-angle lens or a telephoto lens. The flash 220 may emit light that is used to reinforce light reflected from an object. According to an embodiment, the flash 220 may include one or more light emitting diodes (LEDs) (e.g., a red-green-blue (RGB) LED, a white LED, an infrared (IR) LED, or an ultraviolet (UV) LED) or a xenon lamp.

The image sensor 230 may obtain an image corresponding to an object by converting light emitted or reflected from the object and transmitted via the lens assembly 210 into an electrical signal. According to an embodiment, the image sensor 230 may include one selected from image sensors having different attributes, such as a RGB sensor, a black-and-white (BW) sensor, an IR sensor, or a UV sensor, a plurality of image sensors having the same attribute, or a plurality of image sensors having different attributes. Each image sensor included in the image sensor 230 may be implemented using, for example, a charged coupled device (CCD) sensor or a complementary metal oxide semiconductor (CMOS) sensor.

The image stabilizer 240 may include various circuitry and move the image sensor 130 or at least one lens included in the lens assembly 210 in a particular direction, or control an operational attribute (e.g., adjust the read-out timing) of the image sensor 230 in response to the movement of the camera module 180 or the electronic device 101 including the camera module 180. This allows compensating for at least part of a negative effect (e.g., image blurring) by the movement on an image being captured. According to an embodiment, the image stabilizer 240 may be implemented, for example, as an optical image stabilizer, and may sense such a movement by the camera module 180 or the electronic device 101 using a gyro sensor (not shown) or an acceleration sensor (not shown) disposed inside or outside the camera module 180.

The memory 250 may store, at least temporarily, at least part of an image obtained via the image sensor 230 for a subsequent image processing task. For example, if image capturing is delayed due to shutter lag or multiple images are quickly captured, a raw image obtained (e.g., a Bayer-patterned image, a high-resolution image) may be stored in the memory 250, and its corresponding copy image (e.g., a low-resolution image) may be previewed via the display device 160. Thereafter, if a specified condition is met (e.g., by a user's input or system command), at least part of the raw image stored in the memory 250 may be obtained and processed, for example, by the image signal processor 260. According to an embodiment, the memory 250 may be configured as at least part of the memory 130 or as a separate memory that is operated independently from the memory 130.

The image signal processor 260 may include various processing circuitry and perform one or more image processing with respect to an image obtained via the image sensor 230 or an image stored in the memory 250. The one or more image processing may include, for example, depth map generation, three-dimensional (3D) modeling, panorama generation, feature point extraction, image synthesizing, or image compensation (e.g., noise reduction, resolution adjustment, brightness adjustment, blurring, sharpening, or softening). Additionally or alternatively, the image signal processor 260 may perform control (e.g., exposure time control or read-out timing control) with respect to at least one (e.g., the image sensor 230) of the components included in the camera module 180. An image processed by the image signal processor 260 may be stored back in the memory 250 for further processing, or may be provided to an external component (e.g., the memory 130, the display device 160, the electronic device 102, the electronic device 104, or the server 108) outside the camera module 180. According to an embodiment, the image signal processor 260 may be configured as at least part of the processor 120, or as a separate processor that is operated independently from the processor 120. If the image signal processor 260 is configured as a separate processor from the processor 120, at least one image processed by the image signal processor 260 may be displayed, by the processor 120, via the display device 160 as it is or after being further processed.

According to an embodiment, the electronic device 101 may include a plurality of camera modules 180 having different attributes or functions. In such a case, at least one of the plurality of camera modules 180 may form a wide-angle camera or a front camera, and at least another of the plurality of camera modules 180 may form a telephoto camera or a rear camera.

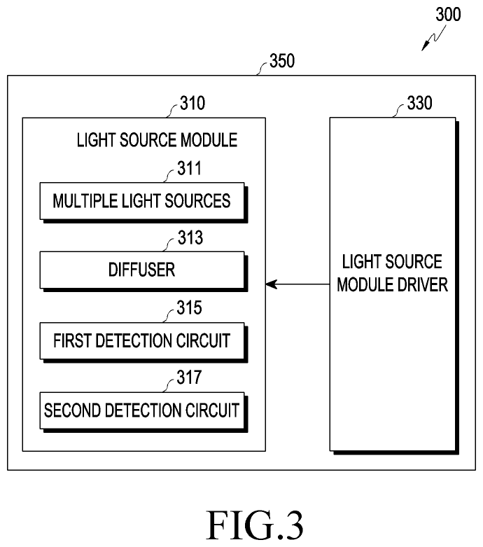

FIG. 3 is a block diagram 300 illustrating an example configuration of a light-emitting control device of a light source according to various embodiments. Referring to FIG. 3, a light-emitting control device 350 of a light source may include a light source module 310 and a light source module driver (e.g., including various circuitry) 330. According to an embodiment, the light-emitting control device 350 of a light source may be included in a camera module (e.g., the camera module 180 of FIG. 2).

The light source module 310 may include multiple light sources 311, a diffuser 313, a first detection circuit 315, and/or a second detection circuit 317.

The multiple light sources 311 each may include a vertical cavity surface emitting laser (VCSEL) array, which is a type of a high-output laser diode.

According to an embodiment, the diffuser 313 may include multiple micro-lens (e.g., a micro-lens array) for diffusing light emitted (or output) from the multiple light sources 311. The multiple micro-lens may be configured to diffuse light emitted from the multiple light sources 311 so as to have a fixed view angle or a beam profile on a space.

The first detection circuit 315 may be configured to detect damage to the diffuser 313. According to an embodiment, the first detection circuit 315 may be configured to receive light reflected from the diffuser 313 so as to change to a current, and to detect damage to the diffuser 313 while monitoring light emitted from the multiple light sources 300 on the basis of the photocurrent amount. The voltage value changed on the basis of the photocurrent amount received in the first detection circuit 315 may be transferred to the light source module driver 330 as a voltage value capable of detecting whether the diffuser 313 is damaged.

According to an embodiment, the first detection circuit 315 may include a photodiode as a light-receiving diode. According to an embodiment, the first detection circuit 315 and the second detection circuit 317 may be formed to be connected in series.

The second detection circuit 317 may be configured to detect damage to the diffuser 313. According to an embodiment, the second detection circuit 317 may include a conductor having a resistance value. For example, the second detection circuit 317 may include Indium Tin Oxide (ITO).

According to an embodiment, the second detection circuit 317 may be formed to surround the diffuser 313 when seen from above a window on which the diffuser 313 is formed. The diffuser 313 may be formed on a first surface of the window, and the second detection circuit 317 may be formed on a second surface of the window, which is positioned opposite to the first surface. The second detection circuit 317 may be formed on the diffuser 313 or around the location of the diffuser 313 to surround, on the second surface, the diffuser 313 or the location of the diffuser 313.

According to an embodiment, the second detection circuit 317 may be configured to transfer, to the light source module driver 330, a predetermined voltage value according to a resistance value of the second detection circuit 317 as a first voltage value indicating that the diffuser is not damaged. In a case where the second detection circuit 317 formed on an outer side surface of the window on which the diffuser is formed is damaged when the diffuser 313 is damaged, a voltage value changed according to a change of a resistance value of the second detection circuit 317 may be transferred to the light source module driver 330 as a second voltage value indicating that the diffuser is damaged.

The light source module driver 330 may include various circuitry and be configured to control the light source module 310. According to an embodiment, the light source module driver 330, using at least one of the first detection circuit 315 or the second detection circuit 317, may be configured to determine whether the diffuser 313 is damaged so as to control light emission of the multiple light sources 311.

According to an embodiment, the light source module driver 330 may be configured to receive a voltage value changed according to the amount of photocurrent detected in the first detection circuit 315, and to control light emission of the multiple light sources 311 on the basis of the received voltage value. The light source module driver 330 may be configured to determine damage to the diffuser 313 and thus to block light emission of the multiple light sources 311 when a voltage value changed according to the amount of photocurrent detected in the first detection circuit 315 is not included within the range of a first set threshold value.

According to an embodiment, the light source module driver 330 may be configured to receive a changed voltage value according to a change of a resistance value of a second detection circuit 317, and to control light emission of the multiple light sources 311 on the basis of the received voltage value. The light source module driver 330 may be configured to determine damage to the diffuser 313 when a voltage value received from the second detection circuit 317 is not included within the range of a set second threshold value, and to control light emission of the multiple light sources 311. When a first voltage value changed according to a resistance value of the second detection circuit 317 is received, the light source module driver 330 may be configured to determine that the diffuser 311 is not damaged. The light source module driver 330 may be configured to determine damage to the diffuser 313 and to block light emission of the multiple light sources 311 when a second voltage value changed according to a change of a resistance value of the second detection circuit 317 is received.

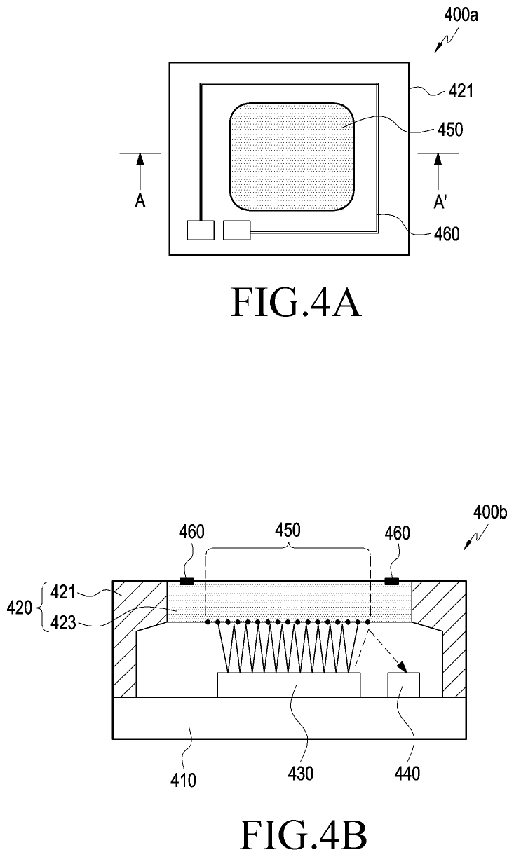

FIG. 4A is a diagram 400a illustrating an example configuration of a light source module of an electronic device according to various embodiments, and FIG. 4B is a cross-sectional view 400b taken along line A-A′ of FIG. 4A according to various embodiments.

Referring to FIG. 4A and FIG. 4B, a light source module of an electronic device may include a circuit board 410, and/or a casing 420.

The circuit board 410 may include a submount having high thermal conductivity in order for heat dissipation.

According to an embodiment, multiple light sources 430 (e.g., the multiple light sources of FIG. 3 or a vertical cavity surface emitting laser (VCSEL) array which is a type of a high-output laser diode) may be mounted on the circuit board 410.

According to an embodiment, a first detection circuit 440 (e.g., the first detection circuit 315 of FIG. 3) may be mounted on the circuit board 410 to be adjacent to the multiple light sources 430. For example, the first detection circuit 440 may include a photodiode. The first detection circuit 440 may be mounted on an area in the circuit board 410, which can receive light reflected from a diffuser 450 (e.g., the diffuser 313 of FIG. 3).

The casing 420 may be provided to surround at least a part of the circuit board 410, or may be mounted on a surface of the circuit board 410 to accommodate the multiple light sources 430 and/or the first detection circuit 440.

The casing 420 may include a body 421 made of a metal material or a synthetic resin material and a window 423 made of a glass material or a polyimide material. The window 423 may be mounted to the body 421. The casing 420 may be coupled to the circuit board 410.

According to an embodiment, the body 421 may be mounted on the circuit board 410 and may be formed to surround at least a portion of an area in which the multiple light sources 430 and the first detection circuit 440 are arranged.

According to an embodiment, the diffuser 450 for diffusing light emitted from the multiple light sources 430 mounted on the circuit board 410 may be formed in the window 423. For example, the diffuser 450 may include multiple micro-lenses.

According to an embodiment, the first detection circuit 440 may be configured to receive light reflected from the diffuser 450 so as to change to a current, and to transfer a voltage value changed on the basis of the received photocurrent amount to a light source module driver (e.g., the light source module driver 330 of FIG. 3) so as to determine whether the diffuser 450 is damaged.

According to an embodiment, the second detection circuit 460 (e.g., the detection circuit 317 of FIG. 3) may be formed on the window 423 to surround the diffuser 450. For example, the second detection circuit 460 may include a conductor.

According to an embodiment, a voltage value according to a change of a resistance value of the second detection circuit 460 may be transferred to a light source module driver such that whether the diffuser 450 is damaged may be determined.

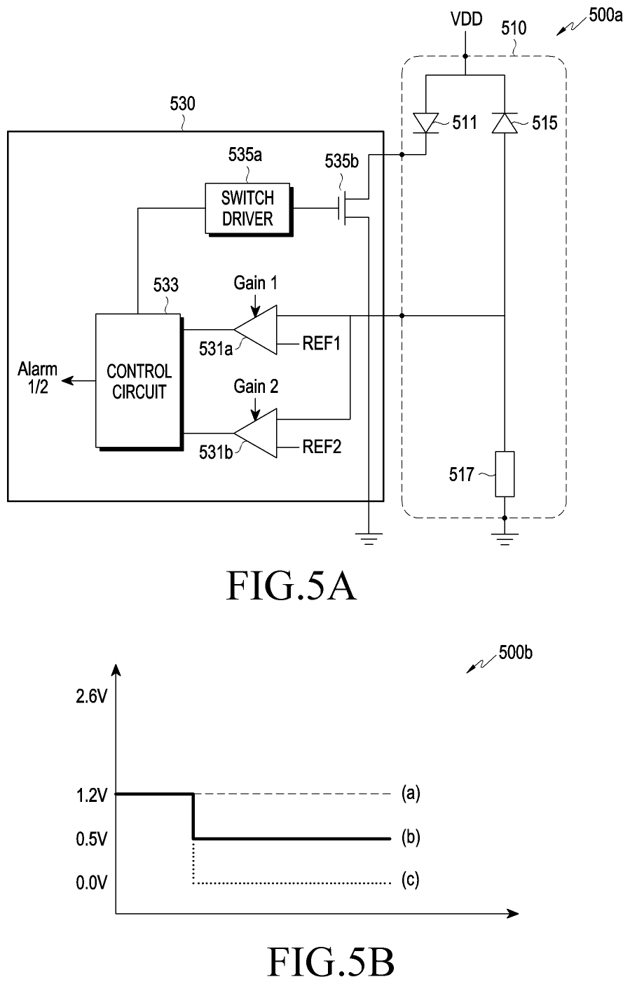

FIG. 5A is a circuit diagram 500a illustrating an example circuit for controlling a light source module in an electronic device according to various embodiments.

Referring to FIG. 5A, a camera module (e.g., the camera module 180 of FIG. 2) of an electronic device (e.g., the electronic device 101 of FIG. 1) may include a light source module (e.g., including circuitry) 510 and a light source module driver (e.g., including circuitry) 530 capable of controlling the light source module 510.

The light source module 510 may include multiple light sources 511 (e.g., the multiple light sources 311 of FIG. 3, the multiple light sources 430 of FIG. 4B, or a diode), a first detection circuit 515 (e.g., the first detection circuit 315 of FIG. 3, the first detection circuit 440 of FIG. 4B, or a photodiode), and/or a second detection circuit 517 (e.g., the second detection circuit 317 of FIG. 3, the second detection circuit 460 of FIG. 4A-FIG. 4B, a conductor, or Indium Tin Oxide (ITO)). The first detection circuit 515 and the second detection circuit 517 may be connected in series.

The light source module driver 530 (e.g., the light source module driver 330 of FIG. 3) may include a first comparator 531a configured to compare a voltage value received from the first detection circuit 515 of the light source module 510 with the range of a set first threshold value, a second comparator 531b configured to compare a voltage value received from the second detection circuit 517 of the light source module 510 with the range of a set second threshold value, and a control circuit 533 configured to determine whether a diffuser (e.g., the diffuser 313 of FIG. 3 or the diffuser 450 of FIG. 4A-FIG. 4B) is damaged on the basis of output signals received from the first comparator 531a and the second comparator 531b and configured to inform a user of same or to control (e.g., maintain or block) emission of light in the multiple light sources 511 (e.g., the multiple light sources 311 of FIG. 3 or the multiple light sources 430 of FIG. 4A-FIG. 4B) when it is determined that the diffuser has been damaged. When the control circuit 533 transmits, to a switch driver 535a, a control signal for controlling (e.g., maintaining or blocking) light emitted from the multiple light sources 511, the switch driver 535a may be configured to control a switch 535b so as to control (e.g., maintain or block) emission of light in the multiple light sources 511.

While light is emitted from the multiple light sources 511 and a diffuser diffuses light emitted from the multiple light sources 511, the first detection circuit 515 may be configured to receive light reflected from the diffuser so as to change to a current. When a resistance value of the first detection circuit 515 changes according to a photocurrent amount detected in the first detection circuit 515 and a voltage value in the first detection circuit 515 changes according to a change of the resistance value in the first detection circuit 515, the changed voltage value in the first detection circuit 515 may be transferred to the first comparator 531a. The first comparator 531a may be configured to compare a voltage value input from the first detection circuit 515 with the range of the set first threshold value, and to output the output signal according to the result through the comparison to the control circuit 533. The control circuit 533 may be configured to determine whether a diffuser is damaged on the basis of the output signal received from the first comparator 531a, and to transfer, according to the determination, a control signal to the switch driver 535a which controls the switch 535b capable of controlling light emitted from the multiple light sources 511.

For example, in a normal operation state in which a diffuser is not damaged, when the photocurrent amount received in the first detection circuit 515 is 400 uA, a voltage value of 1.2 V transferred to the first comparator 531a is included within the range (e.g., a voltage value of 0.6 V or more) of the set first threshold value so that emission of light in multiple light sources can be maintained. However, when the photocurrent amount received in the first detection circuit 515 reduces to 110 uA due to damage to the diffuser, a voltage value of 0.5 V transferred to the first comparator 531a is not included within the range (e.g., a voltage value of 0.6 V or more) of the set first threshold value so that emission of light in multiple light sources may be blocked.

A voltage value changed according to a change of a resistance value of the second detection circuit 517 may be transferred to the second comparator 531b of the light source module driver 530. The second comparator 531b may be configured to compare a voltage value input from the second detection circuit 517 with the range of the set second threshold value, and to output an output signal according to the result through the comparison to the control circuit 533. The control circuit 533 may be configured to determine whether a diffuser is damaged on the basis of the output signal received from the second comparator 531b, and to transfer, according to the determination, a control signal to the switch driver 535a which controls the switch 535b capable of controlling light emitted from the multiple light sources 511.

For example, in a normal operation state in which a diffuser is not damaged, the second detection circuit 517 may transfer a voltage value of 1.2 V corresponding to a resistance value of the second detection circuit 517 to the second comparator 531b, the voltage value of 1.2 V is included within the range (e.g., a voltage 0.1 V or more) of the set second threshold value, and thus emission of light in multiple light sources can be maintained. However, when the second detection circuit 517 formed on an outer side surface of the diffuser is damaged due to damage to the diffuser, the second comparator 531b may receive a voltage value of 0 V from the second detection circuit 517, the voltage value of 0 V is not included within the range (e.g., a voltage 0.1 V or more) of the set second threshold value, and thus emission of light in multiple light sources may be blocked.

FIG. 5B is a graph 500b illustrating a change of a voltage value due to damage to a diffuser in an electronic device according to various embodiment.

Referring to FIG. 5B, (a) illustrates a normal state, in which a voltage value received in a first comparator (e.g., the first comparator 531a of FIG. 5A) or a second comparator (e.g., the second comparator 531b of FIG. 5A) is a 1.2 V which is included within the range (e.g., a voltage value of 0.6 V or more) of the set first threshold value or the range (e.g., a voltage value of 0.1 V or more) of the set second threshold value and a diffuser is not damaged.

Referring to FIG. 5B, (b) illustrates a damaged state of a diffuser, in which a voltage value of 0.5 V changed due to reduction of a photocurrent amount received in a first detection circuit (e.g., the first detection circuit 515 of FIG. 5A) is transferred to a first comparator (e.g., the first comparator 531a of FIG. 5A) and thus emission of light in multiple light sources may be blocked.

Referring to FIG. 5B, (c) illustrates a damaged state of a diffuser, in which a voltage value of 0 V changed according to a change of a resistance value of a second detection circuit (e.g., the second detection circuit 517 of FIG. 5A) is transferred to a second comparator (e.g., the second comparator 531b of FIG. 5A) and thus emission of light in multiple light sources may be blocked.

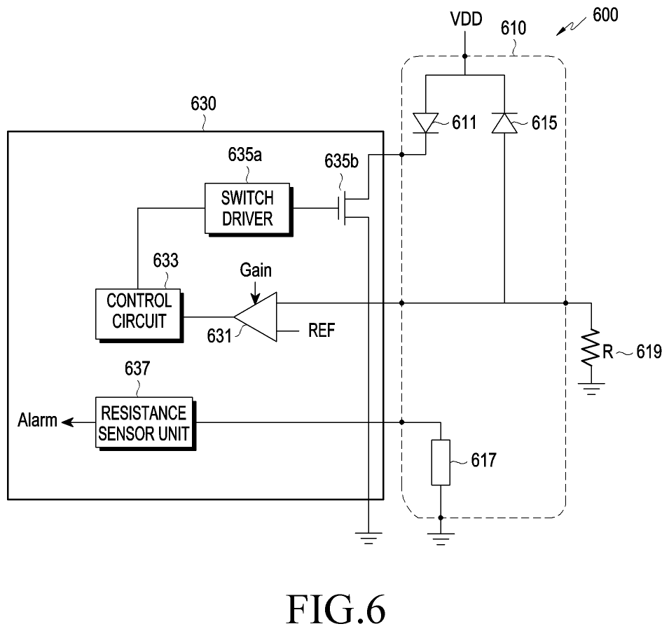

FIG. 6 is a circuit diagram 600 illustrating an example circuit controlling a light source module in an electronic device according to various embodiments.

Referring to FIG. 6, a camera module (e.g., the camera module 180 of FIG. 2) of an electronic device (e.g., the electronic device 101 of FIG. 1) may include a light source module (e.g., including circuitry) 610 and a light source module driver (e.g., including circuitry) 630 capable of controlling the light source module 610.

The light source module 610 may include multiple light sources 611 (e.g., the multiple light sources 311 of FIG. 3, the multiple light sources 430 of FIG. 4B, or a diode), a first detection circuit 615 (e.g., the first detection circuit 315 of FIG. 3, the first detection circuit 440 of FIG. 4B, or a photodiode), a second detection circuit 617 (e.g., the second detection circuit 317 of FIG. 3, the second detection circuit 460 of FIG. 4A-FIG. 4B, a conductor, or Indium Tin Oxide (ITO)), and/or a first resistance circuit 619 connected to the first detection circuit 615.

The light source module driver 630 (e.g., the light source module driver 330 of FIG. 3) may include a comparator 631 configured to compare the range of a set first threshold value with a voltage value received from the first detection circuit 615 of the light source module 610, a control circuit 633 configured to determine whether a diffuser (e.g., the diffuser 313 of FIG. 3 or the diffuser 450 of FIG. 4A-FIG. 4B) is damaged according to an output signal of the comparator 631 and configured to inform a user of same or to control (e.g., maintain or block) emission of light in the multiple light sources 611 (e.g., the multiple light sources 311 of FIG. 3 or the multiple light sources 430 of FIG. 4B) when it is determined that a diffuser has been damaged. When the control circuit 633 transmits, to a switch driver 635a, a control signal for controlling (e.g., maintaining or blocking) light emitted from the multiple light sources, the switch driver 635a may control a switch 635b to control (e.g., maintain or block) emission of light in the multiple light sources 611 (or the multiple light sources 430 of FIG. 4B).

The light source module driver 630 may include a resistance sensor unit 637. The resistance sensor unit 637 may include various circuitry and be configured to detect a resistance value received from the second detection circuit 617, and to output an alarm indicating the danger of when a resistance value received from the second detection circuit 617 is not included within the range of a set second threshold value.

While light is emitted from the multiple light sources 611 and a diffuser diffuses light emitted from the multiple light sources 611, the first detection circuit 615 may be configured to receive light reflected from the diffuser so as to change to a current. When a resistance value of the first detection circuit 615 changes according to a photocurrent amount received in the first detection circuit 615 and a voltage value in the first detection circuit 615 changes due to a change of the resistance value of the first detection circuit 615, the changed voltage value in the first detection circuit 615 may be output to the comparator 631. The comparator 631 may be configured to compare a voltage value received from the first detection circuit 615 with the range of a set first threshold value, and to output an output signal according to the result through the comparison to the control circuit 633. The control circuit 633 may be configured to determine whether a diffuser is damaged on the basis of an output signal received from the comparator 631, and may be configured to transfer, according to the determination, a control signal for controlling light emitted from the multiple light sources 611 to the switch driver 635a capable of controlling a switch 635b.

The resistance sensor unit 637 of the light source module driver 630 may be configured to detect a change of a resistance value of the second detection circuit 617 so as to inform a user of same. When a resistance value received from the second detection circuit 617 is not included within the set first threshold value, the resistance sensor unit 637 may be configured to output an alarm including a sound, a message, or the like so as to inform a user of the danger.

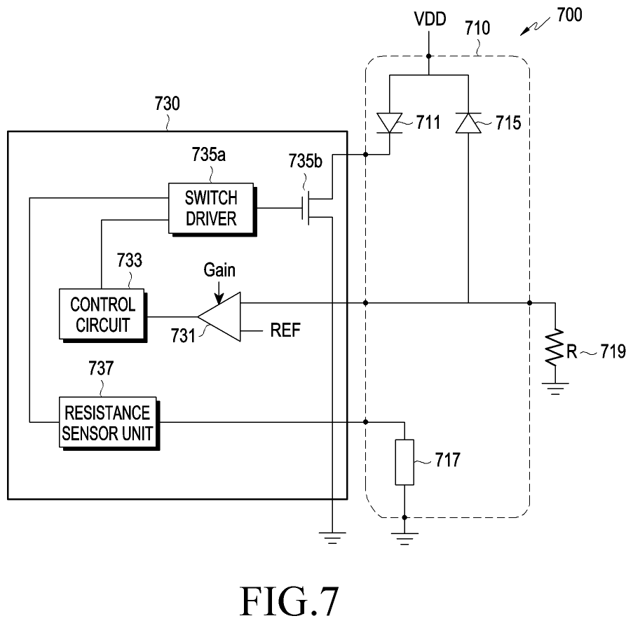

FIG. 7 is a circuit diagram 700 illustrating an example circuit for controlling a light source module in an electronic device according to various embodiments.

Referring to FIG. 7, a camera module (e.g., the camera module 180 of FIG. 2) of an electronic device (e.g., the electronic device 101 of FIG. 1) may include a light source module (e.g., including circuitry) 710 and a light source module driver (e.g., including circuitry) 730 capable of controlling the light source module 710.

The light source module 710 may include multiple light sources 711 (e.g., the multiple light sources 311 of FIG. 3, the multiple light sources 430 of FIG. 4B, or a diode), a first detection circuit 715 (e.g., the first detection circuit 315 of FIG. 3, the first detection circuit 440 of FIG. 4B, or a photodiode), a second detection circuit 717 (e.g., the second detection circuit 317 of FIG. 3, the second detection circuit 460 of FIG. 4A-FIG. 4B, a conductor, or Indium Tin Oxide (ITO)), and/or a first resistance circuit 719 connected to the first detection circuit 715 in series.

The light source module driver 730 (e.g., the light source module driver 330 of FIG. 3) may include a comparator 731 configured to compare a voltage value received from the first detection circuit 715 of the light source module 710 with the range of a set first threshold value, or a control circuit 733 configured to determine whether a diffuser (e.g., the diffuser 313 of FIG. 3 or the diffuser 450 of FIG. 4A-FIG. 4B) is damaged according to an output signal of the comparator 731 and configured to inform a user of same or to control (e.g., maintenance or block) of emission of light in the multiple light sources 711 when it is determined that the diffuser has been damaged. When the control circuit 733 transmits, to a switch driver 735a, a control signal for controlling (e.g., maintaining or blocking) light emitted from the multiple light sources, the switch driver 735a may be configured to control a switch 735b so as to control (e.g., maintain or block) emission of light in the multiple light sources 711.

The light source module driver 730 may include a resistance sensor unit 737. The resistance sensor unit 737 may include various circuitry and be configured to detect a resistance value received from the second detection circuit 717, and when a resistance value received from the second detection circuit 717 is not included within the range of a set second threshold value, configured to output an alarm indicating danger or to transfer a sign indicating damage to a diffuser to the control circuit 733. The control circuit 733 may be configured to transfer, to the switch driver 735a, a control signal for controlling (e.g., maintaining or blocking) light emitted from the multiple light sources when a signal that a diffuser is damaged is received from the resistance sensor unit 737.

While light is emitted from the multiple light sources 711 and a diffuser diffuses light emitted from the multiple light sources 711, the first detection circuit 715 may be configured to receive light reflected from the diffuser so as to change to a current. When a resistance value of the first detection circuit 715 changes according to a photocurrent amount received in the first detection circuit 715 and a voltage value in the first detection circuit 715 changes due to a change of the resistance value of the first detection circuit 715, the changed voltage value in the first detection circuit 715 may be output to the comparator 731. The comparator 731 may be configured to compare a voltage value received from the first detection circuit 715 with the range of a set first threshold value, and configured to output an output signal according to the result through the comparison to the control circuit 733. The control circuit 733 may be configured to determine whether a diffuser is damaged on the basis of an output signal received from the comparator 731, and configured to transfer, according to the determination, a control signal for controlling light emitted from the multiple light sources 711 to the switch driver 735a capable of controlling a switch 735b.

The resistance sensor unit 737 of the light source module driver 730 may be configured to detect a change of a resistance value of the second detection circuit 717. When a resistance value received from the second detection circuit 717 is not included within the set first threshold value, the resistance sensor unit 737 may be configured to transfer a signal indicating damage to a diffuser to the control circuit 733. When a signal indicating damage to a diffuser is received from the resistance sensor unit 737, the control circuit 733 may be configured to transfer a control signal (e.g., block) to the switch driver 735a capable of controlling the switch 735b.

According to various example embodiments, an electronic device (e.g., the electronic device 101 of FIG. 1) may include: a circuit board (e.g., the circuit board 410 of FIG. 4B), multiple light sources (e.g., the multiple light sources 311 of FIG. 3 or the multiple light sources 430 of FIG. 4) mounted on the circuit board, a first detection circuit (e.g., the first detection circuit 315 of FIG. 3 or the first detection circuit 440 of FIG. B) arranged adjacent to the multiple light sources and mounted on the circuit board, and a casing (e.g., the casing 420 of FIG. 4B) including a body (e.g., the body 421 of FIG. 4B) mounted on the circuit board and configured to surround at least a portion of an area in which the multiple light sources and the first detection circuit are arranged, and a window (e.g., the window 423 of FIG. 4B) mounted on the body facing the multiple light sources, wherein the window may include a diffuser (e.g., the diffuser 313 of FIG. 3 or the diffuser 450 of FIG. 4A-FIG. 4B) formed on at least one surface thereof and configured to diffuse light emitted from the multiple light sources, and a second detection circuit (e.g., the second detection circuit 317 of FIG. 3 or the second detection circuit 460 of FIG. 4A-FIG. 4B) at least partially surrounding the diffuser on an outer surface of the window.

According to various example embodiments, the first detection circuit may include a light-receiving diode configured to receive light reflected from the diffuser.

According to various example embodiments, the first detection circuit may include a photodiode.

According to various example embodiments, the second detection circuit may include a conductor having a resistance value.

According to various example embodiments, the second detection circuit may comprise Indium Tin Oxide (ITO).

According to various example embodiments, the first detection circuit and the second detection circuit are connected in series.

According to various example embodiments, a light source driver configured to determine whether the diffuser is damaged using at least one of the first detection circuit or the second detection circuit and configured to control light emission of the multiple light sources based on whether the diffuser is damaged may be further included.

According to various example embodiments, the light source driver may be configured to receive a voltage value changed according to an amount of photocurrent detected in the first detection circuit and configured to control light emission of the multiple light sources based on the received voltage value.

According to various example embodiments, the light source driver may be configured to block light emission of the multiple light sources based on the received voltage value not being included within the range of a set threshold value.

According to various example embodiments, the light source driver may be configured to receive a voltage value based on a change of a resistance value of the second detection circuit and to control light emission of the multiple light sources based on the received voltage value.

According to various example embodiments, the light source driver may be configured to block light emission of the multiple light sources based on the received voltage value not being included within the range of a set threshold value.

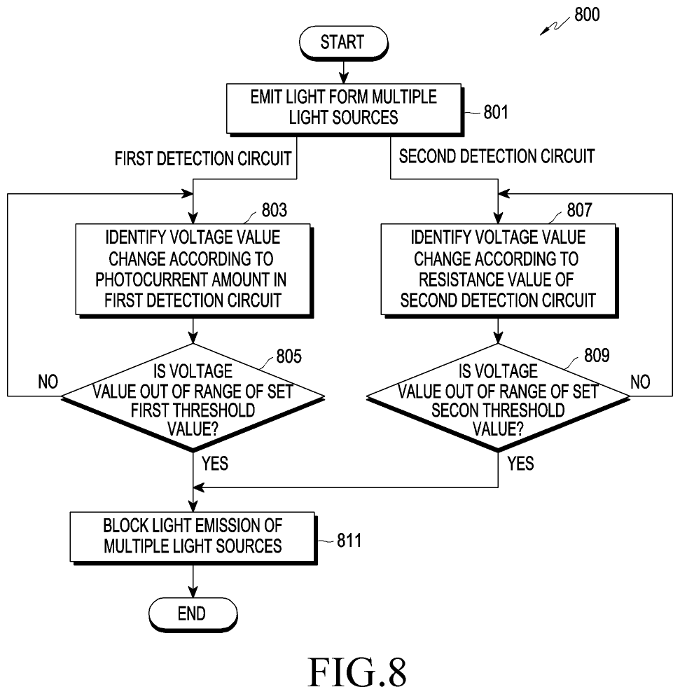

FIG. 8 is a flowchart 800 illustrating an example operation of controlling a light source module in an electronic device according to various embodiments. The light source module control operation may include operations 801, 803, 805, 807, 809 and 811 (which may be referred to as operations 801 to 811). The light source module control operation may be performed by at least one of an electronic device (e.g., the electronic device 101 of FIG. 1), at least one processor (e.g., the processor 120 of FIG. 1) of the electronic device, or a light source module driver (e.g., the light source module driver 330 of FIG. 3). According to an embodiment, at least one of an operations 801 to 811 may be omitted, the orders of some operations thereof may be changed, or another operation may be added thereto.

Referring to FIG. 8, in an operation 801, an electronic device (e.g., the light source module driver 330 of FIG. 3) may be configured to control emission of light in multiple light sources (e.g., the multiple light sources 311 of FIG. 3 or the multiple light sources 430 of FIG. 4B) of a light source module (e.g., the light source module 310 of FIG. 3).

In an operation 803, an electronic device (e.g., the light source module driver 330 of FIG. 3) may be configured to identify a voltage value changed on the basis of a change of a photocurrent amount of a first detection circuit (e.g., the first detection circuit 315 of FIG. 3 or the first detection circuit 440 of FIG. 4B) of a light source module (e.g., the light source module 311 of FIG. 3).

In an operation 805, an electronic device (e.g., the light source module driver 330 of FIG. 3) may configured to determine whether a voltage value changed on the basis of a change of a photocurrent amount of a first detection circuit (e.g., the first detection circuit 315 of FIG. 3 or the first detection circuit 440 of FIG. 4B) is included within the range of a set first threshold value.

In the operation 805, when a voltage value changed on the basis of a change of a photocurrent amount of a first detection circuit is not included within the range of the set first threshold value, in an operation 811, an electronic device (e.g., the light source module driver 330 of FIG. 3) may be configured to block emission of light in multiple light sources (e.g., the multiple light sources 311 of FIG. 3 or the multiple light sources 430 of FIG. 4B). In the operation 805, when a voltage value changed on the basis of a change of a photocurrent amount of a first detection circuit is included within the range of the set first threshold value, an electronic device (e.g., the light source module driver 330 of FIG. 3) may be configured to maintain emission of light in multiple light sources.

In the operation 801, an electronic device (e.g., the light source module driver 330 of FIG. 3) may be configured to control so as to emit light in multiple light sources (e.g., the multiple light sources 311 of FIG. 3 or the multiple light sources 430 of FIG. 4B) of a light source module (e.g., the light source module 310 of FIG. 3).

In an operation 807, an electronic device (e.g., the light source module driver 330 of FIG. 3) may be configured to identify a voltage value changed on the basis of a change of a resistance value of a second detection circuit (e.g., the second detection circuit 317 of FIG. 3 or the second detection circuit 460 of FIG. 4B) formed on a window (e.g., the window 423 of FIG. 4B) on which a diffuser (e.g., the diffuser 313 of FIG. 3 or the diffuser 450 of FIG. 4A-FIG. 4B) is formed.

In an operation 809, an electronic device (e.g., the light source module driver 330 of FIG. 3) may be configured to determine whether a voltage value changed on the basis of a change of a resistance value of a second detection circuit (e.g., the second detection circuit 317 of FIG. 3 or the second detection circuit 460 of FIG. 4B) is included within the range of a set second threshold value.

In the operation 809, when a voltage value changed on the basis of a resistance value of a second detection circuit is not included within the range of the set second threshold value, in an operation 811, an electronic device (e.g., the light source module driver 330 of FIG. 3) may be configured to block emission of light in multiple light sources (e.g., the multiple light sources 311 of FIG. 3 or the multiple light sources 430 of FIG. 4B). In the operation 809, when a voltage value changed on the basis of a change of a resistance value of a second detection circuit (e.g., the second detection circuit 317 of FIG. 3 or the second detection circuit 460 of FIG. 4B) is included within the range of the set second threshold value, an electronic device (e.g., the light source module driver 330 of FIG. 3) may be configured to maintain emission of light in multiple light sources.

According to various example embodiments, a method for controlling an output of a light source of an electronic device (e.g., the electronic device 101 of FIG. 1) may include: emitting light from multiple light sources (e.g., the multiple light sources 311 of FIG. 3 or the multiple light sources 430 of FIG. 4B), determining whether a diffuser (e.g., the diffuser 313 of FIG. 3 or the diffuser 450 of FIG. 4A-FIG. 4B) configured to diffuse light emitted from the multiple light sources is damaged using at least one of a first detection circuit (e.g., the first detection circuit 315 of FIG. 3 or the first detection circuit 440 of FIG. 4B) or a second detection circuit (e.g., the second detection circuit 317 of FIG. 3 or the second detection circuit 460 of FIG. 4B) included in the electronic device during emitting light from the multiple light sources, and controlling light emission of the multiple light sources based on the determination of whether the diffuser is damaged.

According to various example embodiments, the first detection circuit may include a light-receiving diode configured to receive light reflected from the diffuser.

According to various example embodiments, the first detection circuit may include a photodiode.

According to various example embodiments, the second detection circuit may include a conductor having a resistance value.

According to various example embodiments, the second detection circuit may comprise Indium Tin Oxide (ITO).

According to various example embodiments, the controlling may include receiving a voltage value changed according to the amount of photocurrent detected in the first detection circuit; and controlling light emission of the multiple light sources based on the received voltage value.

According to various example embodiments, the controlling light emission of the multiple light sources may include blocking light emission of the multiple light sources based on the received voltage value not being included within the range of a set threshold value.

According to various example embodiments, the controlling may include receiving a voltage value based on a change of a resistance value of the second detection circuit, and controlling light emission of the multiple light sources based on the received voltage value.

According to various example embodiments, the controlling light emission of the multiple light sources may include blocking light emission of the multiple light sources based on the received voltage value not being included within the range of a set threshold value.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

In connection with a storage medium in which commands are stored, the commands are configured to cause, when executed by at least one processor, the at least one processor to perform at least one operation, and the at least one operation may include one or more of an operation of emitting light from multiple light sources, an operation of determining whether a diffuser for diffusing light emitted from the multiple light sources is damaged using at least one of a first detection circuit or a second detection circuit included the electronic device during emitting light from the multiple light sources, and an operation of controlling light emission of the multiple light sources based on the determination of whether the diffuser is damaged.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents.

What is claimed is:

1. An electronic device comprising:
a circuit board;
multiple light sources mounted on the circuit board;
a first detection circuit arranged adjacent to the multiple light sources and mounted on the circuit board; and
a casing comprising a body mounted on the circuit board and configured to surround at least a portion of an area in which the multiple light sources and the first detection circuit are arranged, and a window mounted on the body facing the multiple light sources,
wherein the window comprises a diffuser formed on at least one surface of the window and configured to diffuse light emitted from the multiple light sources, and
a second detection circuit formed to at least partially surround the diffuser on the outer surface of the window.

2. The electronic device of claim 1, wherein the first detection circuit comprises a light-receiving diode configured to receive light reflected from the diffuser,
the second detection circuit comprises a conductor having a resistance value, and
the first detection circuit and the second detection circuit are connected in series.

3. The electronic device of claim 1, wherein the first detection circuit comprises a photodiode, and the second detection circuit comprises Indium Tin Oxide (ITO).

4. The electronic device of claim 1, further comprising a light source driver comprising circuitry configured to determine whether the diffuser is damaged using at least one of the first detection circuit or the second detection circuit and to control light emission of the multiple light sources based on whether the diffuser is damaged.

5. The electronic device of claim 4, wherein the light source driver is configured to receive a voltage value changed based on an amount of photocurrent detected in the first detection circuit and to control light emission of the multiple light sources based on the received voltage value.

6. The electronic device of claim 5, wherein the light source driver is configured to block light emission of the multiple light sources based on the received voltage value not being included within a range of a set threshold value.

7. The electronic device of claim 4, wherein the light source driver is configured to receive a voltage value based on a change of a resistance value of the second detection circuit and to control light emission of the multiple light sources based on the received voltage value.

8. The electronic device of claim 7, wherein the light source driver is configured to block light emission of the multiple light sources based on the received voltage value not being included within a range of a set threshold value.

9. A method for controlling an output of a light source of an electronic device, the method comprising:
emitting light from multiple light sources;
determining whether a diffuser configured to diffuse light emitted from the multiple light sources is damaged using at least one of a first detection circuit or a second detection circuit included the electronic device when emitting light from the multiple light sources; and
controlling light emission of the multiple light sources based on the determination of whether the diffuser is damaged.

10. The method of claim 9, wherein the first detection circuit comprises a light-receiving diode configured to receive light reflected from the diffuser, and
the second detection circuit comprises a conductor having a resistance value.

11. The method of claim 9, wherein the first detection circuit comprises a photodiode, and the second detection circuit comprises Indium Tin Oxide (ITO).

12. The method of claim 9, wherein the controlling comprises:
receiving a voltage value changed based on an amount of photocurrent detected in the first detection circuit; and
controlling light emission of the multiple light sources based on the received voltage value.

13. The method of claim 12, wherein the controlling of light emission of the multiple light sources comprises blocking light emission of the multiple light sources based on the received voltage value not being included within a range of a set threshold value.

14. The method of claim 9, wherein the controlling comprises:
receiving a voltage value based on a change of a resistance value of the second detection circuit; and
controlling light emission of the multiple light sources, based on the received voltage value.

15. The method of claim 14, wherein the controlling of light emission of the multiple light sources comprises blocking light emission of the multiple light sources based on the received voltage value not being included within a range of a set threshold value.
